(19) United States
(12) Patent Application Publication
(10) Pub. No.: US 2016/0330503 A1
(43) Pub. Date: Nov. 10, 2016

(54) DUAL-HEIGHT RF TUNER SHIELD

(71) Applicant: THOMSON LICENSING, Issy-Les Moulineaux (FR)

(72) Inventors: William John TESTIN, Indianapolis, IN (US); Mickey Jay HUNT, Camby, IN (US); William Hofmann BOSE, Nashville, IN (US)

(21) Appl. No.: 15/110,572

(22) PCT Filed: Nov. 25, 2014
(86) PCT No.: PCT/US14/67272

§ 371 Date: Jul. 8, 2016

Related U.S. Application Data
(60) Provisional application No. 61/924,905, filed on Jan. 8, 2014.

(51) Int. Cl. H04N 21/41; H05K 9/00; H05K 1/02

(52) U.S. Cl. CPC H04N 21/41; H05K 1/0216; H05K 1/0243; H05K 9/006

(57) ABSTRACT

An electronic device is provided that has a vertical chassis wall with an aperture, a horizontal circuit board that extends toward the vertical chassis wall, F-connector connected to the horizontal circuit board and extending out of the a vertical chassis wall through the aperture and dual height inner RF shield that covers part of the F-connector and other electronic components. The height of the RF is greater over the F-connector than over some of the other electronic components.

### CROSS-REFERENCE TO RELATED APPLICATIONS

This application claims the benefit of U.S. Provisional Application Ser. No. 61/924,905, filed Jan. 8, 2014, which is incorporated by reference herein in its entirety.

### TECHNICAL FIELD

The present principles relate generally to electronic devices and, more particularly, to electronic devices having metal shields in the vicinity of a printed circuit board.

### BACKGROUND

The market preference for set top boxes and the like (such as computers, game consoles, DVD players, CD players, etc.) is to have such devices be small, compact, and versatile. However, such preferences increasingly challenge the designers, because set top boxes and the like are required to perform more functions, which require more internal components. This results in more challenges to appropriately manage the heat generated by some of these components in these crowded devices, which is potentially detrimental to the device's longevity and performance. This crowding also results in more challenges to appropriately shield some components from the risk of electrostatic discharge and/or from interference (such as from radiofrequency interference) to and from other components and external sources.

To appropriately guard at-risk components, the common closed polygon vertical wall metal structures (i.e. shields) have been employed, which are secured generally to a printed circuit board. However, the devices that employ such shields tend to be items that are mass produced in high volume production environments. As such, the soldering of shields in high volume production environments require rapid processing that requires the need for inspection of the mounted components contained within the shields and shields themselves.

A further challenge that has been observed in some devices such as satellite receivers with at least one F-connector requiring radiofrequency (RF) interference suppression has been the need to further employ an opposing metal shield (opposite the shield on the printed circuit board) configured to be mounted on the underside of the printed circuit board. The underneath opposing shield encloses a point of connection of a center connector of the at least one F-connector to the printed circuit board.

Additionally, the need for such RF interference suppression has required the shields themselves having large vertical dimensions to adequately surround the F-connector.

In crowded devices, the F-connectors are required to be located in close proximities to other components on the printed circuit board and each of these components themselves can require shielding. However, the shielding requirements for the different component can be uniquely different. In such cases, some have employed multiple shields. While others have employed a shield assembly 200 such as that shown in FIG. 2 in which the height of the entire shield assembly, which can be a tuner shield assembly, is made at one large or full height in an effort appropriately shield all of the vulnerable components contained therein. Here, the use of F-connectors 210 often dictates the height of the shielding for all of the components in the region. This view shows that the shield assembly 200 includes a shield 212 having vertical walls and a shield cover 211 that covers the components captured within each of the shield rooms made by the vertical walls. In fact, the high vertical walls have been found to be quite beneficial to their intended shielding purpose.

In some crowded devices that now employ F-connectors and other components that require individual shielding that sufficiently shields the components from each other and from external sources, one unitary structure is used as the shield. The unitary structures unfortunately not only require additional production time, but also make reworking and/or sample inspection more challenging. As such, the need exists for a shield and a shield cover with a more efficient design to make reworking and/or spot sample inspection easier.

With the above challenges in mind and the increasing demand of the market for set top boxes to include F-connectors and/or other components requiring shielding on printed circuit boards, the objectives of the present principles effectively address the above mentioned challenges.

### SUMMARY OF THE PRESENT PRINCIPLES

A set top box is disclosed that includes a vertical chassis wall having an aperture; a horizontal circuit board that extends toward the vertical chassis wall; an F-connector connected to the horizontal circuit board (either under or over the board) and extending out of the vertical chassis wall through the aperture; and inner shield (which can generally be used to contain/shield the RF circuit components mounted on the circuit board), wherein the inner shield comprises two parts: a proximal part near the F-connector that has a larger height and a distal part away from the F-connector that has a smaller height.

The present principles can also include an electronic device (1) having an outer casing (2, 3, 4, 6); a horizontal printed circuit board (501) within the outer casing; a radiofrequency shield (312) on the printed circuit board, the radiofrequency shield having a higher height region (316) that forms a higher height shield room (313B) and a lower height shield region (317) that forms a lower height shield room (313A); a first electronic component (10) in the higher height shield room; and a second electronic component (504) in the lower height shield room. The electronic device can have at least one wall (318) of the higher height shield room being higher than all walls of the lower height shield room. A shield cover (311) can be included that covers the radiofrequency shield, the first electronic component and the second electronic component. The shield can include ribs or indents (336) that are on outside upstanding side walls (321) of the radiofrequency shield; and attachment springs (334) extending from an upper plate (331, 333, 330) of the shield cover in which the attachment springs grasp the ribs or indents to secure the shield cover to the radiofrequency shield. The upper plate (331, 333, 330) can have a contour that follows a contour of top edges of the walls that defines the higher height shield room and the lower height shield room. The principles can include at least one other first component in at least one other higher height shield room or at least one other second electronic component in at least one other lower height shield room and/or the higher height shield room and the lower height shield room share one wall (321, 322), which can be an interior wall (321). The outside upstanding side walls (321) of the radiofrequency shield can alternatively have a textured surface for the attachment springs (334) to contact and secure the cover to the shield.

The present principles can also include an electronic device (1) having an outer casing (2, 3, 4, 6); a horizontal printed circuit board (501) within the outer casing; one or more first electronic components (10) and one or more second electronic components (504) over or on the printed circuit board (501); and a radiofrequency shield (312) on the printed circuit board, the radiofrequency shield having outside upstanding side walls (321) surrounding the first and second electronic components and surrounding at least one interior upstanding wall (322), one of the outside upstanding side walls being a back wall (318). The radiofrequency shield includes a higher height region (316) that completely or partially surrounds the one or more first electronic components in which the higher height region includes at least part of the back wall and includes at least part of one other of the outside upstanding side walls or at least part of the at least one interior upstanding wall; and a lower height region (317) that completely or partially surrounds the one or more second electronic component in which the lower height region includes at least part of another of the outside upstanding side walls or at least another part of the at least one interior upstanding wall. At least part of the higher height region is taller than all of the lower height region. The higher height region can have one or more higher height shield rooms (313B) that each contain the one or more first electronic components and the lower height shield region that includes at least one lower height shield rooms (313A) that each contain the one or more second electronic components. The electronic device can include an intermediate region (315) in the radiofrequency shield between the higher height region and the lower height region, wherein at least one wall in the intermediate region slopes downward as the at least one wall extends from the higher height region to the lower height region.

### BRIEF DESCRIPTION OF THE DRAWINGS

The present principles may be better understood in accordance with the following exemplary figures, in which:

FIG. 1 shows a perspective rear view of an electronic device that employs a dual height tuner shield according to the current principles;

FIG. 2 shows a perspective disassembled view of a known single height tuner shield assembly;

FIG. 3 shows perspective views of the shield cover and dual height tuner shield according to the current principles;

FIG. 4 is a top plan view of the dual height tuner shield according to the current principles;

FIG. 5 shows a perspective view of the shield cover and dual height tuner shield on a printed circuit board according to the current principles;

FIG. 6 is a perspective view of one shield cover according to the current principles;

FIG. 7 shows views of the vertical fingers or flaps of the shield cover according to the current principles;

FIG. 8 is sectional view of the vertical fingers or flaps of the shield cover in the vicinity of the F-connector according to an embodiment of the current principles;

FIG. 9 is sectional view of the vertical fingers or flaps of the shield cover in the vicinity of the F-connector according to another embodiment of the current principles;

FIG. 10 is a sectional view of one F-connector assembly shielded by the shield and shield cover according to an embodiment of the current principles; and

FIG. 11 is a flowchart for the method of forming the electronic device according to the current principles.

### DETAILED DESCRIPTION

The invention will now be described in greater detail in which embodiments of the present principles are illustrated in the accompanying drawings.

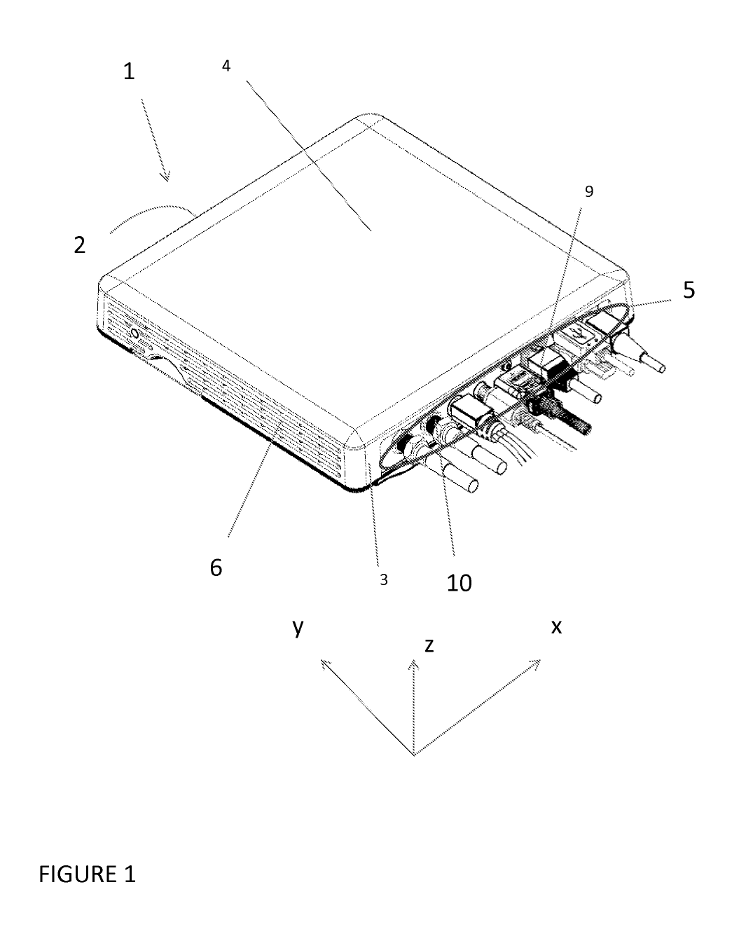

FIG. 1 shows an electronic device 1 having a front wall 2, rear wall 3, top 4, and side walls 6 according to the present principles. The electronic device 1 can be a set top box or the like (such as computers, game consoles, DVD players, CD players, etc.) that further includes a panel jack 5 for connecting cables 9, wherein one of the electrical connectors can be an F-connector 10 or the like. This view with the plurality of cables 9 connected to the electrical connectors on the panel jack 5 is indicative of how crowded the components within the electronic device 1 can be. As such, such electronic devices 1 which can have a tuner or the like will require a tuner shield. In this view, one of the electrical connectors on the panel jack 5 can be an F-connector 10 and some other connector that can be connected to some internal component requiring shielding.

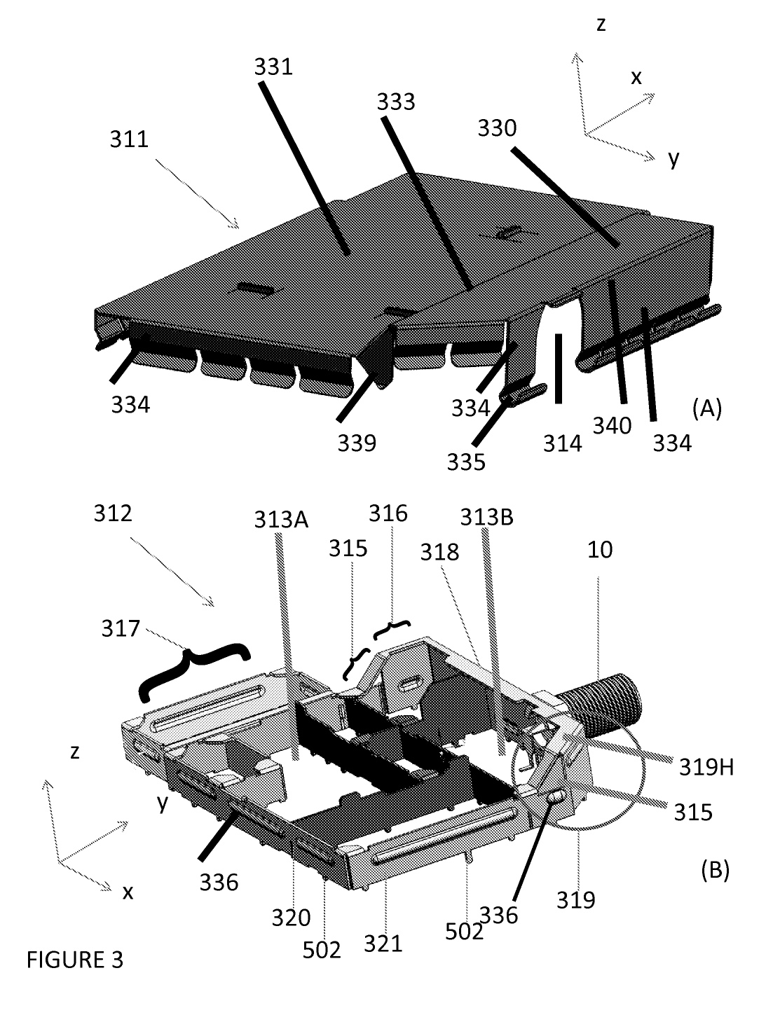

FIGS. 3A and 3B show perspective views of the shield cover 311 and the dual height tuner shield 312 according to the present principles. FIG. 3B most clearly shows the dual height feature of the tuner shield 312 in which the lower height region 317 transitions from the higher height region 316 as the shield extends away from the back wall 318 of the shield along the horizontal y-axis, wherein the comparative heights are gauged along the z-axis. The shield back wall 318 can be parallel to the rear wall 3 of the electronic device 1 along the x-axis.

A key advantage of the invention is that the lower height region 317 makes it easier to repair, optically inspect and troubleshoot the shield 312 and the components contained within the shield 312 after the shield is affixed. Further, this lower height region 317 makes it easier to finish and/or complete the manufacture of the electronic device 1. The lower height region 317 allows for easier soldering and inspecting of the components within the shield and the shield 312 itself, wherein the ease of soldering is enhanced, because the lower height region 317 can have relatively shallow walls. The shallow walls make it easier to see inside the walls of the shield 317 at various stages of manufacturing and after some of these stages, which include thermal processing stages that can often cause components to move and/or change in some respects.

It should be noted that the cover 311 can have holes or slots therein depending on the requirements of the electronic device and the components therein. The quantity, size, shape, orientation and position of the holes and slots that can be tolerated will depend and/or be dictated by the wavelengths of the applicable radiofrequency waves.

The shield 312 can be a unitary structure of one folded metal sheet with designed bends and joints, which can be analogous to Origami art. Folded corners 319 can be present and can increase stability. The folded corners 319 include adjacent vertical wall portions and can include a horizontal wall portion 319H extending from the vertical wall portions.

Alternatively, the shield 312 can be partly a unitary structure of one folded metal sheet with designed bends and joints and can include added vertical walls as needed which can be employed to enhance shielding or enhance stability.

The shield 312 in FIG. 3B has been determined to be effective when an F-connector 10 is employed and connected to the rear wall 3. Because the F-connector is relatively large and the F-connector's positioning is dictated by the required geometry of the electronic device 1 and the required positioning of the horizontal printed circuit within the electronic device 1, the interior part of the F-connector 10 within the electronic device and through the shield back wall 318 tends to be relatively high in the vertical z-axis compared to other components which can be positioned away from the shield back wall 318.

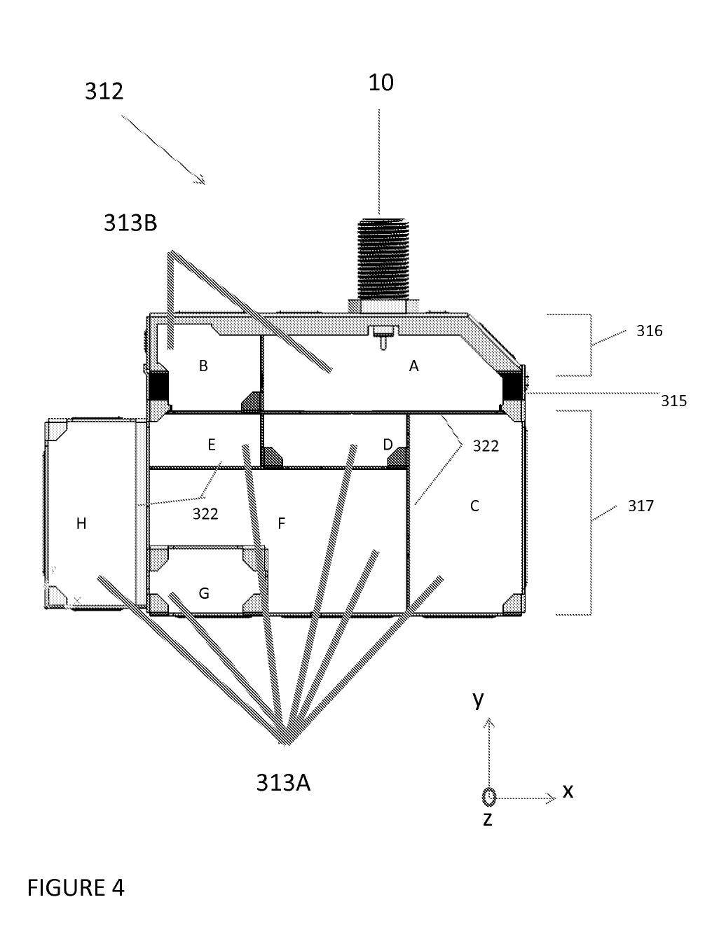

FIG. 4 is a top plan view of the shield 312 in FIG. 3B which shows that the shield 312 can include a series of shield rooms (A, B, C, D, E, F, G, H) made by the vertical walls. The shield rooms can classified as the higher height rooms 313B and the lower height rooms 313A. Both types of rooms 313A, 313B can include interior walls 322.

In alternative embodiments, the shield 312 can be attached to the printed circuit board 501 through reflow-soldering.

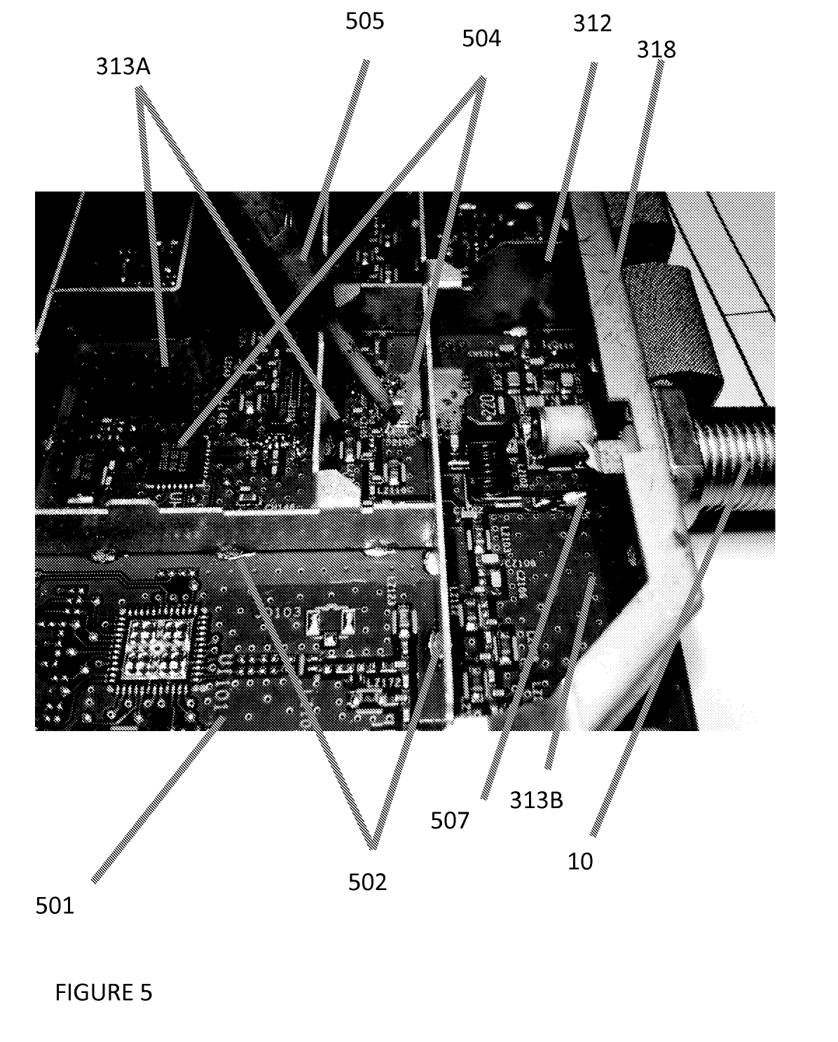

FIG. 5 shows a perspective view of the shield 312 attached to a printed circuit board 501 at contact points 502, which can be solder points. This view shows the soldering or reworking of flat, low or shallow components or second components 504 which can be chip components within the separate shielded wall areas in the lower height rooms 313A by a solder probe, iron or tool 505, wherein these flat, low or shallow components 504 lay lower than the F-connector 10. This view shows how the higher height rooms 313B accommodate the F-connector 10. The F-connector 10 can be considered a first component at the shield back wall 318.

Also, it should be understood that the first components 10 can be components other than an F-connectors and can be positioned at dimensions from the surface of the printed circuit such that a larger height requirement shield back wall 318 is needed. Such first components which require shielding can also be part of the other electrical connectors on the panel jack 5.

Further, the current principles are applicable to such for first components which are not F-connector and are not necessarily electrical connectors, but do require shielding and require the higher height regions 316

In alternative embodiments, the dual height shield is designed to allow the use of a standard-height swage-attached F-connector. In such cases, the majority of other components (i.e. shallow components or second components 504 that lay lower than the first components 10) contained by the shield 312 that can be shielded by lower height walls are specifically positioned away from the shield back wall 318 or further from the shield back wall 318 than the F-connector and/or other first components. With such a layout, most of the components are conveniently positioned for easy testing and rework even with the shield 312 attached.

In sum, an electronic device 1 such as a set top box is disclosed that includes a vertical chassis wall 3 having an aperture; a horizontal circuit board that extends toward the vertical chassis wall; F-connector 10 connected to the horizontal circuit board which can be under or over the horizontal circuit board and extending out of the a vertical chassis wall through the aperture; and an inner shield 312 which can generally be used to contain/shield the RF circuit components mounted on the printed circuit board on the interior side of the vertical chassis wall and connected to the F-connector. The inner shield comprises a series of vertical peripheral walls that surround components under or over the printed circuit board in which the higher height region 316 (or proximal portion of the vertical peripheral walls) that are connected or close to the F-connector are larger than the height of the lower height region 317 (or distal portion of the of the vertical peripheral walls) that is away from the F-connector.

In an alternative embodiment, the shield back wall 318 can be parallel to and adjacent to the vertical chassis rear wall 3, the shield front wall 320 can be opposite the shield back wall 318, and at least two outside vertical side wall portions 321 can extend from the shield back wall 318 to the shield front wall 320. The shield walls can be linear are can have bends. The shield back wall, shield front wall, and outside vertical side wall portions comprise the series of vertical peripheral walls. The proximal portion 316 of the vertical peripheral wall is the back wall 318 and the portions of the outside vertical side wall portions connected to the back wall 318 in proximity of the back wall. Proximal portion 316 of the shield near or toward the back wall 318 has a larger height than the distal portion 317 of the vertical peripheral wall near or toward the front wall 320. The outside vertical side wall portions 321 can have an intermediate region 315 in which the proximal portion transitions to the distal portion which is the region where the height of the peripheral wall reduces from a larger height to a lower height.

In embodiments, the shield 312 can further have interior vertical walls 322 that extend from interior sides of the shield back wall 318, front wall 320, and/or outside vertical sides wall portions 321 and/or other interior vertical walls 322. For example, some of the interior vertical walls such as those used to form shield rooms D and E as shown in FIG. 4 extend to and from other interior vertical walls 322. The collection of interior vertical walls and vertical peripheral walls make a series of separate shielded wall areas, rooms, or compartments, wherein there can be full height shield areas which are proximate the F-connector or first components 10 and associated with the larger height shield regions 316 of the walls and there can be a lower height shield region 317 which is remote from the F-connector or first components 10 and associated with the lower height region of the walls. The larger height dimension of the walls can be positioned such that the larger height is larger than the height or upper vertical position of the F-connector or first components 10. The F-connector or first component 10 can be cylindrical and the larger height dimension of the shield can extend beyond the top vertical positions of the F-connector and other first components 10. The smaller height dimension of the walls can be positioned such that it is smaller or lower than the height of the F-connector or first components and the smaller height dimension can be positioned such that the lowest position is lower than the bottom vertical position of the barrel portion of F-connector and it highest vertical position is located between the lowest and highest positions of the barrel portion of the F-connector.

The electronic device 1 can further include a top or shield cover 311 as shown in FIG. 3B for the shield 312 in which the shield cover 311 includes an upper plate having at least three portions: a proximate cover portion 330 that covers the proximal portion or the higher height region 316 of the vertical peripheral walls, a distal cover portion 331 that covers the distal portion 317 of the vertical peripheral walls, and intermediate cover portion 333 that covers the intermediate region 315 of the vertical peripheral walls, wherein the proximal portion 316 transitions to the distal portion 317.

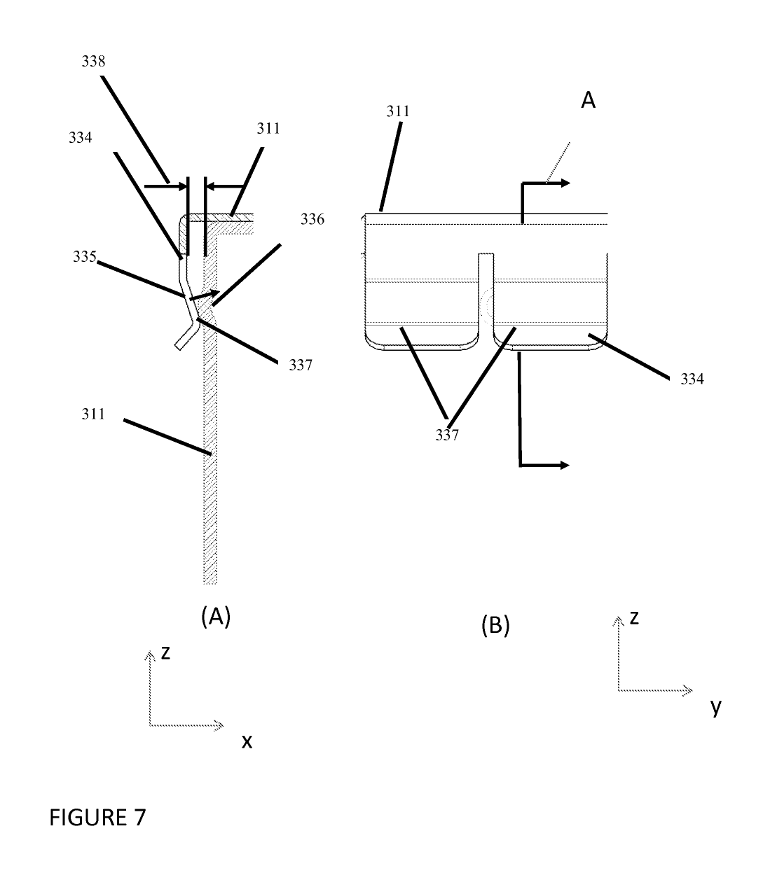

These portions 330, 331, 333 can be planar and the perimeter of the shield cover 311 can have generally vertical fingers or flaps or spring clips 334 and extend perpendicularly from the peripheral edge of the shield cover, wherein the fingers or flaps or spring clips 334 extend over the exterior sides of the vertical peripheral walls as shown in FIG. 7. FIG. 7B shows a plan front view of fingers 334 and FIG. 7A shows a cross section view of the fingers 334 cut along slice A in FIG. 7B. The fingers 334 can have edges 335 that bend inward and then outward as they extend from the top cover to create grasping portion 337 which extend over ribs or engage indents 336 in the vertical peripheral walls to secure the top cover to the shield. The fingers or flaps can be flexible and the design of the fingers 334 can be such that a gap 338 exists between the interior upper vertical portion of the finger and the corresponding exterior upper vertical portion of the shield wall. Such a gap 338 can be advantageous in that it provides some manufacturing tolerance for cover formation and it permits the cover 311 to be placed on and removed from the shield 312 without the need for significant force. In some designs, a gasket or extra shielding can be placed in the gap 338 to prevent possible RF interference around the gap 338. However, gaskets or extra shield material adds cost and makes the shield cover 311 more difficult to apply and remove.

FIG. 3A further shows that vertical fingers or flaps 334 can be omitted along a part of the rear edge 340 of the shield cover 311 to make a slot 314 for the F-connector 10 to allow the shield cover 311 to fit over the shield 312 with the F-connector 10 attached. The rear edge 340 of the shield cover 311 aligns with the shield back wall 318. This view in FIG. 3B shows a preferred arrangement in which vertical fingers or flaps 334 along the rear edge 340 are longer than the vertical fingers or flaps 334 on the side edges or other edges of the shield cover 311.

There are a number of advantages to having a tuner shield with two different heights. One is the tuner shield height is reduced in the area where most of the chip components are located making it easier for the production test equipment to verify component placement and proper soldering while still allowing a standard F-connector to be used. Another is the reduced height of the tuner shield also makes it easier for product development as well as to fix solder issues and/or correct setting of components during production. Additionally, the reduced height of the tuner shield reduces the overall mass of the metal tuner shield which minimizes the amount of time needed in the reflow oven to bring the tuner wrap up to the temperature needed to solder the tuner shield to the printed circuit board. This allows the time needed in the reflow oven to be optimized for proper soldering of the components rather than just setting a minimum time to insure the shield solders.

The present principles have been developed as an improvement of prior set top box designs which employed several high order input filters. In some of these set top boxes two separate shielded areas were employed in which one area employed a standard height shielded area that contained a standard F-connector and the other area having input filters employed a second shielded area in which the shield height was roughly half the height of that of the first shielded. Applicants have recognized that this approach also led to manufacturing difficulties in that it was challenging to optically inspect the solder joints in the area with the taller shield wall around the parts. Also, it is was difficult to perform touch-up soldering in the area due to the difficulty of getting a soldering iron into the small shielded rooms within the shield, wherein the individual shielded rooms are needed to prevent the various tuner filters from talking/interfering to each other. The factory conditions are such that the large mass of the taller tuner wrap or shield controlled the amount of time the entire assembly had to dwell in the reflow oven to guarantee that the metal gets hot enough to form a good solder joint between the tuner shield and the solder connection to the ground plane on the printed circuit board.

FIG. 4 illustrates the dual-height concept in which the area near the F-connector 10 needs to have a height of 5 mm to allow a standard “swaged” F-connector to be used. One of the concerns with the present principles was whether the designed shield would insure that there was adequate clearance between the center conductor 507 of the F-connector and any ground in the area. This is needed to insure that the F-connector has a good return loss (minimal reflection at 75 ohms). If the height of the shield was reduced before the center conductor of the F-connector transitioned into the printed circuit board where the impedance was controlled, the return loss of the connector could fall below the required system performance. By keeping roughly approximately 2 mm between the center conductor and any part of the shield 312, the F-connector can meet the return loss requirements. Tests with a full-height and a dual-height version of the tuner shield were performed and the overall performance of the dual-height tuner shield was better. By extending the full-height area of the tuner shield to include at least approximately 2 mm clearance on each side of the F-connector center conductor, measurements of return loss on the F-connector remained equivalent to the measurements on the known full-height tuner shield. Additionally, the shield 312 was effective enough under conditions in which there were several other components such as a large wire-wound LNB (low-noise block) supply coil and a GDT (gas discharge device) relatively close to the F-connector. Other components can require the taller tuner shield vertical walls as the F-connector to prevent shorting or coupling to the grounded metalwork which can include the shield cover 311. Further, not only was optical verification of soldered areas improved by being able to view more of the solder joints as compared to the taller shields, it was found that the time required to heat the tuner shield in the reflow oven was reduced due to the reduced mass.

An additional concern regarding the design according to the current principles was whether a single tuner shield cover 311 could fit over the dual-height shield 312 properly and be effective. The sloping transition between the full-height area and the reduced height shield is an embodiment in which the intermediate cover region 333 in FIG. 3A covers the intermediate region 315 of the vertical peripheral walls includes a sloping transition and has been found to be effective. The intermediate cover region 333 as a sloping cover region has actually minimized standing waves and provided a gradual transition between the two shield heights. Testing for RF performance was satisfactory, but Radiated Immunity Testing (which exposes the entire set top box to a 3V/m field) showed issues with the corners of the tuner shield in the transition area. Two changes were employed to correct the corner issues. The shield 312 being folded metal sheet with designed bends and joints, which can be analogous to Origami art with folded corners 319, not only increase mechanical stability, but provided a way to close an open corner in the shield. The second was to make a tab 339 in the shield cover 311 that extends down from the upper plate (331, 333, 330) and add a bump or projection 336 on the vertical wall portion of the folder corners 319 such that the tab 339 engages the bump or projection 336, thereby insuring a ground connection at the transition between the full-height and reduced-height shields. The tab can be a plane flat structure. FIGS. 3A and 3B show that the tab 339 can extend down from the intermediate cover region 333 to the a bump or projection 336 in the intermediate region 315.

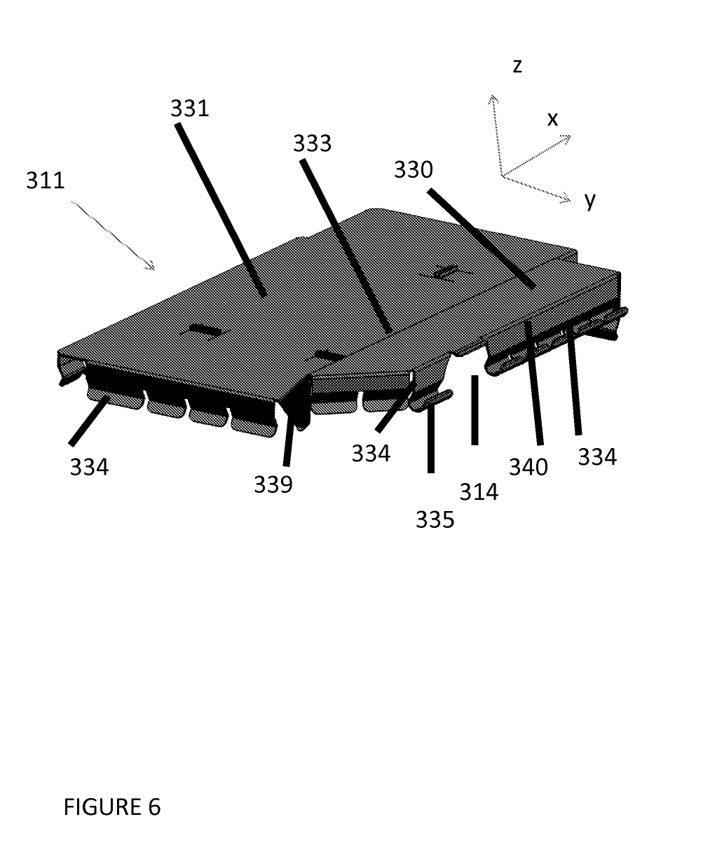

FIG. 3A shows the presently preferred shield cover 311 in which fingers or flaps 334 along the rear edge 340 are longer than the vertical fingers or flaps 334 on the side edges or other edges of the shield cover 312. This arrangement is presently preferred to the arrangement shown in FIG. 6 in which the vertical fingers or flaps 334 along the rear edge 340 are similar or the same in length to the vertical fingers or flaps 334 on the side edges or other edges of the shield cover 312.

The design in FIG. 6 can be a preferred design in some devices in which Radiated Immunity Testing is not an important requirement or is somewhat relaxed, because the shield cover will use less material and can be easier to attach to the shield.

The design in FIG. 3A, however, by adding length to the vertical fingers or flaps 334 along the rear edge 340 has corrected the Radiated Immunity Testing deficiency and has improved a secondary Radiated Immunity Issue by having the fingers 334 of the top cover fit tightly.

Further testing has shown that that having the upper plate (331, 333, 330) being solid without holes improves the rigidity of the shield cover 311 to enhance the gripping of the fingers 334.

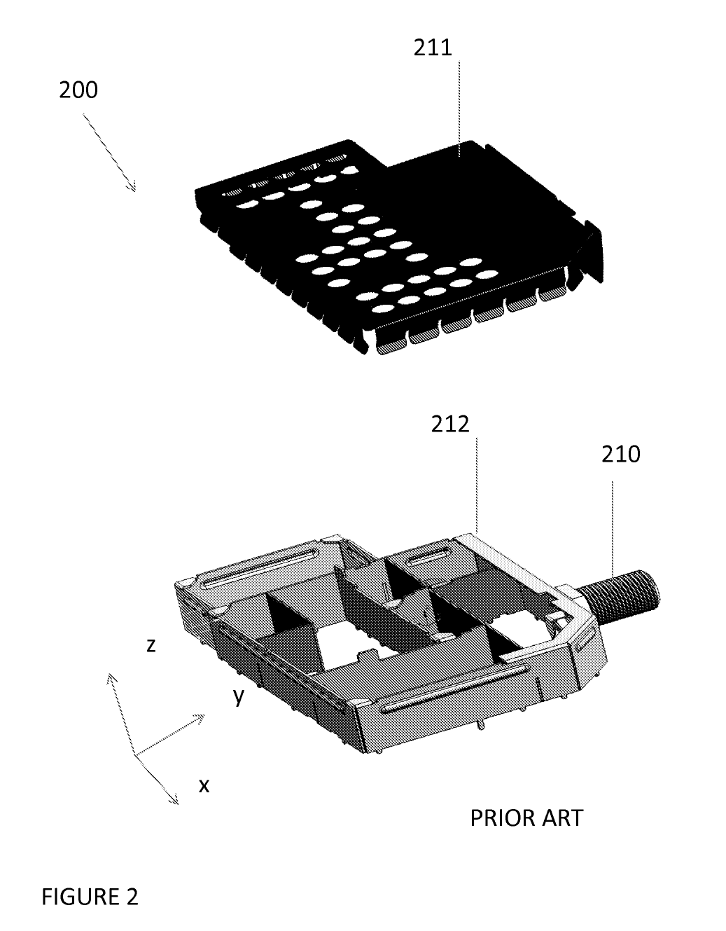

It is recognized, however, that vent holes in the upper plate (331, 333, 330) may be necessary in some designs for heat management, because some of the components contained within the shield 312 can generate heat which may need to be dissipated. As such, having vent holes in the shield cover 311 is one embodiment of the present principles. Although the vent holes such as those shown in the known shield cover 200 in FIG. 2 themselves may not be a problem for RF ingress depending on the wavelength involved, one must recognize that their presence can reduced the rigidity of the shield cover 311 and can thus reduce the gripping strength of the fingers 334. Hence, when vents are employed, use of the finger arrangement in FIG. 3A may be preferred over that in FIG. 6.

An additional concern of the shield 312 was the capability of the shield 312 to pick up harmonics from the DDR (dual data rate memory) into the F-connector. Experimentation has, however, showed that by grounding the tuner shield 312 to a metal chassis of the set top box at the level of the printed circuit board advantageously minimizes any common-mode ground between the printed circuit board and F-connector, thereby mitigating such pick up.

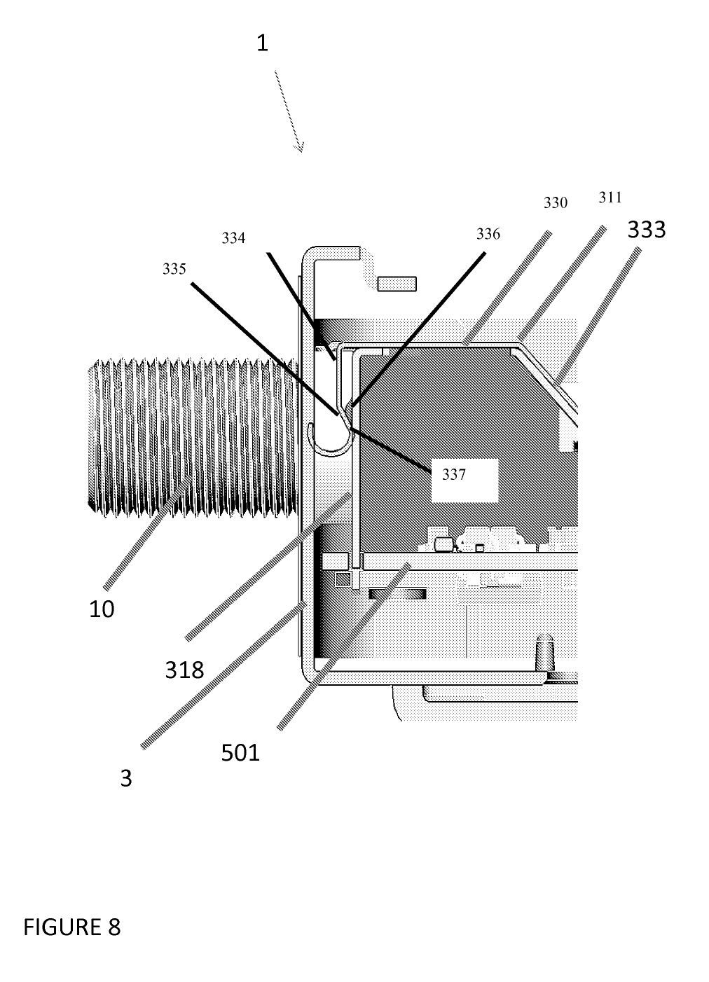

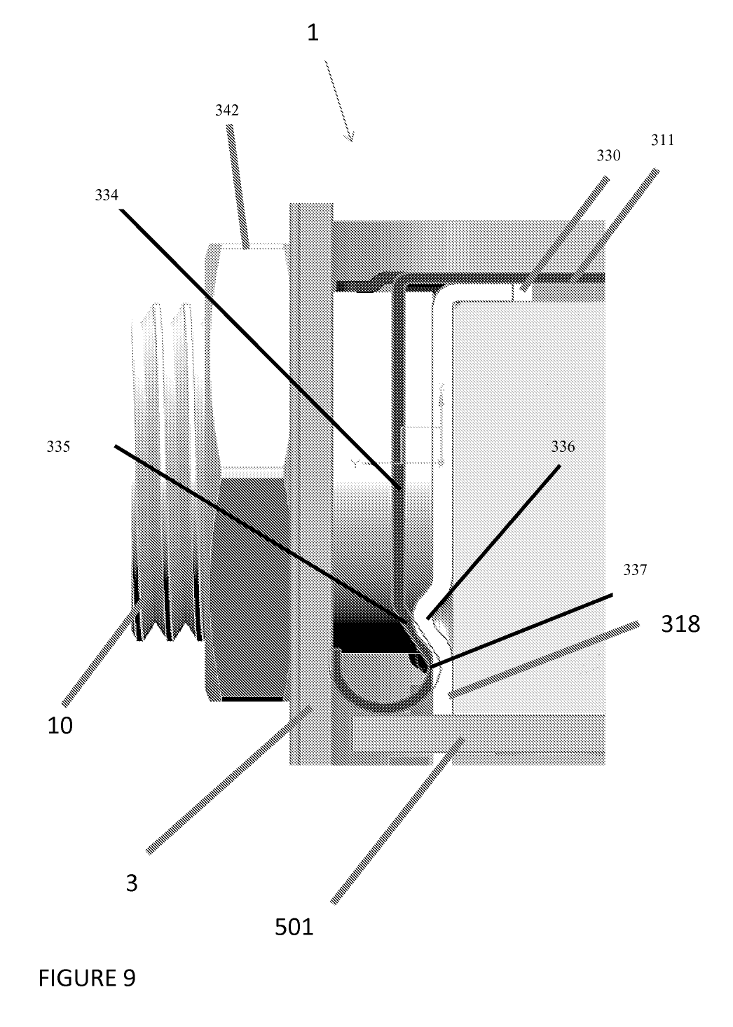

FIGS. 8 and 9 are sectional views of the electronic device 1 illustrating two embodiments of the current principle in which different vertical fingers or flaps 334 of the shield cover 311 in the vicinity of the F-connector 10 are employed. Both views show the fingers 334 can have edges 335 that bend inward and then outward as they extend from the top cover to create grasping portion 337 which extend over ribs or engage indents 336 in the vertical peripheral walls and in particular in the shield back wall 318 to secure the top cover to the shield. The difference in the embodiments is that in FIG. 9 the fingers 334 is longer than in FIG. 8, and, as such the fingers in FIG. 8 engage the indents 336 at a lower position than in FIG. 8. Note that FIG. 9 show the F-connector nut 342 engaged on the F-connector and in FIG. 8, the nut 342 has not been applied yet. FIGS. 8 and 9 omit interior components connected to the F-connector to more clearly focus on the fingers 334. Testing of the devices in FIGS. 8 and 9 revealed that with shield 311 electrically connected to the metal chassis (or the rear wall 2) the common mode problem with DDR current travelling through the F-connector ground back to the chassis was advantageously eliminated. The electrical connection in part can be the edge 335 of the finger 334 contacting the rear wall 3 of the chassis. However, in order to provide a more efficient grounding, the finger arrangement in FIG. 9 in which the fingers 334 were moved to below the middle of the shield back wall 318 to a grounding point on or just above the printed circuit board 501. This repositioning in FIG. 9 resulted in eliminating the problem with harmonics.

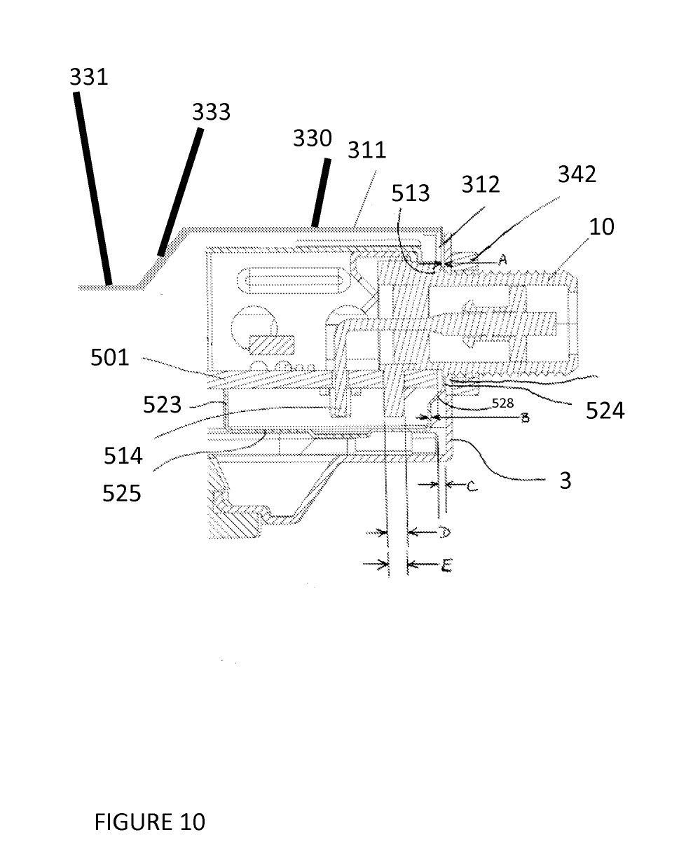

Although having the F-connector 10 and its components and grounding features above the printed circuit board is preferred, the current principles include embodiments in which some components and/or grounding features can be on the opposite side of the printed circuit board 501 as shown in FIG. 10. This construction and others can include the use of the metal RF interference suppressor 523 which can be below the printed circuit board 501. The interference suppressor 523 can be considered the known opposing metal shield.

Here, the F connector nut 342 is shown on the F-connector body 513. The F-connector tab 524 can have an offset 528 that starts just below the bottom edge of the printed circuit board 501. This allows the F-connector tab 524 to bend and be displaced relative to the bottom 525 of the suppressor. The F connector tab 524 can be separated from the side walls of the suppressor 523 and the side walls of the suppressor 523 can be flush with the edge of the printed circuit board 501. This prevents the side walls of the suppressor 523 from being loaded by contact with the inside wall of the vertical chassis rear wall 3, and further allows the tab 524 to be compressed between the inner tuner shield 312 and vertical chassis rear wall 3 when the nut 342 is secured onto the threaded portion of the F-connector 10 on the outside of the vertical chassis rear wall 3.

The tab 524 on the F-connector can have a preferred thickness in the range of 1.8 +0.0-0.1 mm. FIG. 10 shows various gaps A-E which are defined as follows:

A=F-connector shoulder to frame gap, which can be 0.05 mm;

B=thickness of the wall of the suppressor 523, which can be 0.25 mm to 0.5 mm;

C=the edge of the printed circuit board 501 to frame gap, which can be 0.5 mm;

D=the printed circuit board slot side for mounting the body of the F-connector to the printed circuit board 501, which can be 1.90±0.125 mm; and

E=the F-connector body tab size, which can be 1.8 +0.0-0.1 mm, inserted into the slot D.

FIG. 10 shows the center pin/conductor 514 on the F-connector 10 on the underside of the printed circuit board 501. The suppressor 523 covers the center pin/conductor 514 to suppress RF interference under the board. The bottom of the board 501 can be covered with a grounded copper foil (not shown) except for the center pin 514 of the F-connector 10.

The construction of the F-connector 10 is such that the center pin 514 can go through the printed circuit board 501 and have a solder connection on the underside thereof. The center pin 514 can be by the inner shield 312 in the region of the proximate cover portion 330 region where the vertical peripheral walls are at the highest levels. This small point of connection can be shielded to prevent pick-up of spurious signals from the high speed digital portions of a receiver, for example, that generated from the Double Data Rate synchronous dynamic random access memory (DDR), for example, and other components on the bottom side of the PCB 501 and reflected off the inside of the metal enclosure of the device which can be a satellite receiver. Such signal can be picked up on the center pin 514 of the F-connector 10 that protrudes through the printed circuit board 501.

In addition, a component of the currents from the digital portions of the receiver can be present in the ground plane surrounding the pin 514. Thus, the suppressor 523 provides a Faraday shield around the center pin 514 to reduce reflected pickup as well as preventing a current differential across the ground plane surrounding the center pin 514. The Faraday shielding also reduces a source of ingress be outside interference such as broadcast television and cell phones.

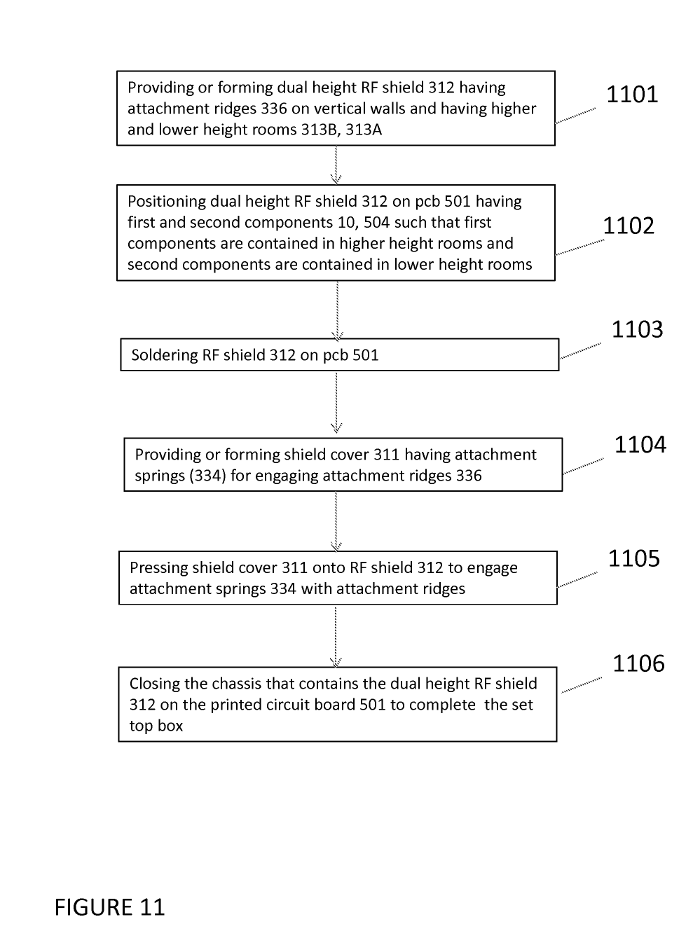

FIG. 11 is a flowchart for the method of forming the electronic device 1 according to the current principles. Step 1101 involves providing or forming the dual height tuner shield 312. In this step the attachment ridges 336 can be formed on vertical walls through stamping, for example, and the higher and lower height rooms 313B, 313A can be formed by the appropriate folding of a metal sheet to form an outer periphery. Interior vertical walls can be formed from the folding and/or inserted after the folding to create the various rooms. The folding can include making horizontal ledges at multiple corners in the rooms to enhance shielding in those areas. Step 1102 involves positioning dual height RF shield 312 on printed circuit board 501 with the first and second components 10, 504 such that first components 10 are contained in higher height rooms 313B and second components are contained in lower height rooms 313A. Step 1103 involves attaching the shield 312 to the printed circuit board 501 by, for example, soldering. Step 1104 involves providing or forming shield cover 311 having attachment springs 334 for engaging to the attachment ridges 336. Step 1105 involves pressing the shield cover 311 onto the shield 312 to engage attachment springs 334 with attachment ridges. The attachment springs 334 can collectively extend and/or cover in the horizontal dimensions more than 75% of the periphery of the shield. The shield cover can contact the top edges of the each of the rooms for effective shielding in which this contact can be complete along the entire periphery of each room. Step 1106 involves closing a chassis that contains the dual height RF shield 312 on the printed circuit board 501 with the first and second components 10, 504.

Although the illustrative embodiments have been described herein with reference to the accompanying drawings, it is to be understood that the present principles are not limited to those precise embodiments, and that various changes and modifications may be effected therein by one of ordinary skill in the pertinent art without departing from the scope of the present principles. All such changes and modifications are intended to be included within the scope of the present principles as set forth in the appended claims.

Also, it should be noted that expressions such as “vertical,” “horizontal,” “front,” “back,” “top,” bottom,” “upper,” “lower” and “over” are used in the description and claims with regards to certain elements with respect of an arbitrary coordinate system such as that shown in some figures; however, the invention is intended for use in components and/or the electronic devices that may be rotated 90 degrees, 180 degrees or to some other value either about a vertical reference line or a horizontal reference lines. This implies that “horizontal” can mean “vertical” and vice versa, “top” can mean “bottom” and vice versa, etc.

1. A set top box comprising:
an outer casing;
a horizontal printed circuit board within the outer casing;
a radiofrequency shield on the printed circuit board, the radiofrequency shield having a higher height region that forms a higher height shield room and a lower height shield region that forms a lower height shield room;
a first electronic component in the higher height shield room; and
a second electronic component in the lower height shield room.

2. The set top box of claim 1 wherein at least one wall of the higher height shield room is higher than all walls of the lower height shield room.

3. The set top box of claim 2 further comprising a shield cover that covers the radiofrequency shield, the first electronic component and the second electronic component.

4. The set top box of claim 3 further comprising:
ribs or indents that are on outside upstanding side walls of the radiofrequency shield; and
attachment springs extending from an upper plate of the shield cover; wherein the attachment springs grasp the ribs or indents to secure the shield cover to the radiofrequency shield.

5. The set top box of claim 4 wherein the upper plate has a contour that follows a contour of top edges of the walls that defines the higher height shield room and the lower height shield room.

6. The set top box of claim 1 comprising at least one other first component in at least one other higher height shield room or at least one other second electronic component in at least one other lower height shield room.

7. The set top box of claim 2 wherein the higher height shield room and the lower height shield room share one wall.

8. The set top box of claim 7 wherein the one wall is an interior wall.

9. The set top box of claim 3 further comprising:
outside upstanding side walls of the radiofrequency shield having a textured surface; and
attachment springs extending from an upper plate of the shield cover; wherein the attachment springs grasps a textured pattern of the textured surface to secure the shield cover to the radiofrequency shield.

10. An electronic device comprising:
an outer casing;
a horizontal printed circuit board within the outer casing;
one or more first electronic components and one or more second electronic components over or on the printed circuit board; and
a radiofrequency shield on the printed circuit board, the radiofrequency shield having outside upstanding side walls surrounding the first and second electronic components and surrounding at least one interior upstanding wall, one of the outside upstanding side walls being a back wall, wherein the radiofrequency shield further comprises:
a higher height region that completely or partially surrounds the one or more first electronic components, the higher height region includes at least part of the back wall and includes at least part of one other of the outside upstanding side walls or at least part of the at least one interior upstanding wall;
a lower height region that completely or partially surrounds the one or more second electronic component s, the lower height region includes at least part of another of the outside upstanding side walls or at least another part of the at least one interior upstanding wall, at least part of the higher height region is taller than all of the lower height region.

11. The electronic device of claim 10 wherein the higher height region comprises one or more higher height shield rooms that each contain the one or more first electronic components and the lower height shield region that comprises at least one lower height shield rooms that each contain the one or more second electronic components.

12. The electronic device of claim 11 wherein one of the one or more first electronic components is an F-connector.

13. The electronic device of claim 12 wherein:
the back wall of the radiofrequency shield is parallel to a vertical chassis rear wall of the outer casing; and
the F-connector extends from within one of the higher height shield rooms through the back wall of the radiofrequency shield and through the vertical chassis rear wall.

14. The electronic device of claim 13 further comprising a shield cover that covers the radiofrequency shield and the first and second electronic components.

15. The electronic device of claim 14 further comprising attachment springs extending from an upper plate of the shield cover; wherein the attachment springs grasp the outside upstanding side walls of the radiofrequency shield to secure the shield cover to the radiofrequency shield.

16. The electronic device of claim 14 further comprising:
ribs or indents that are on the outside upstanding side walls of the radiofrequency shield; and
attachment springs extending from an upper plate of the shield cover; wherein the attachment springs grasp the ribs or indents to secure the shield cover to the radiofrequency shield.

17. The electronic device of claim 16 wherein the attachment springs positioned along the back wall of the radiofrequency shield are longer than the attachment springs positioned along others of the outside upstanding side walls.

18. The electronic device of claim 11 further comprising an intermediate region in the radiofrequency shield between the higher height region and the lower height region, wherein at least one wall in the intermediate region slopes downward as the at least one wall extends from the higher height region to the lower height region.

19. A method of constructing a set top box comprising the steps of:
providing or forming a dual height tuner shield in which the dual height tuner shield at least in part includes a folded piece of metal and includes at least one higher height room and at least one lower height room, wherein peripheral outer walls of the dual height tuner shield have attachment ridges or slots;
positioning the dual height RF shield on a printed circuit board having at least one first electronic component and at least one second electronic component such that the first components are contained in the higher height rooms and the second components are contained in the lower height rooms;
attaching the dual height RF shield to the printed circuit board;
providing or forming a shield cover having attachment springs for engaging to the attachment ridges;
pressing the shield cover onto the shield to engage the attachment springs with the attachment ridges; and
closing a chassis that contains the dual height RF shield on the printed circuit board with the first and second components.
